(19) United States
(12) Patent Application Publication
(10) Pub. No.: US 2011/0051344 A1
(43) Pub. Date: Mar. 3, 2011

(54) SWITCHING DEVICE

(76) Inventors: Sven Adler, Esslingen (DE); Stefan Sittel, Leonberg (DE)

(21) Appl. No.: 12/868,702

(22) Filed: Aug. 25, 2010

Related U.S. Application Data
(60) Provisional application No. 61/237,086, filed on Aug. 26, 2009.

(30) Foreign Application Priority Data
Aug. 25, 2009 (DE) 10 2009 038 543.6

(51) Int. Cl. H05K 7/00

(52) U.S. Cl. 361/679.08; 361/679.21

(57) ABSTRACT

A switching device with a first personal computer, having a first input device for the input of position information and a first monitor with a first display area for displaying information, and a second personal computer, having a second monitor with a second display area for displaying information, whereby the personal computers are connected by means of a first connection, the personal computers have a first program and the first program assigns the relative position of the position information designated for display to a display area and by means of a switching function redirects the input of the position information and the position information designated for display via the first connection to the personal computer connected to the assigned display area.

This nonprovisional application claims priority to German Patent Application No. 10 2009 038 543.6, which was filed in Germany on Aug. 25, 2009, and to U.S. Provisional Application No. 61/237,086, which was filed on Aug. 26, 2009, and which are both herein incorporated by reference.

### BACKGROUND OF THE INVENTION

1. Field of the Invention

The invention relates to a switching device and a method for switching.

2. Description of the Background Art

Switching devices between personal computers are used, inter alia, for controlling industrial manufacturing processes to control other process devices to which a personal computer is connected, for example, from an input device, i.e., a keyboard and or mouse and/or a touch-sensitive screen, likewise connected to a first personal computer. Particularly in the case of greater safety requirements, for example, in a potentially explosive environment, it is desirable to operate the personal computers located in this environment from a personal computer placed in a safe environment.

A requirement for switching between different personal computers is communication or coordination between the personal computers, which can occur in general in a wireless manner by means of a wireless network and/or in a hard-wired manner by means of a network connection. Hardware-based, so-called KM (keyboard mouse) switching devices, to which a keyboard and a mouse are connected, and which are interconnected to the specific keyboard and mouse inputs to the connected personal computers, are used conventionally for switching between individual personal computers. The monitors connected to the personal computers are switched by means of keyboard commands and/or mouse movements between the individual display areas. A switching device of this type is disclosed in U.S. Pat. No. 7,385,584. A disadvantage in this case is that the number of connectable personal computers is low and the appropriately equipped switching devices are costly. Further, the keyboard must be connected directly to the switching device. It is disadvantageous, further, that a certification must be performed in a subsequent connection of an existing network configuration to a plurality of personal computers for the realization of an external control by the necessary modification of the hardware configuration in safety-relevant areas. Further, it is very costly to change an existing hardware configuration in a potentially explosive environment.

### SUMMARY OF THE INVENTION

It is therefore an object of the invention is to provide a switching device and a method for switching, each of which reduces the disadvantages of the prior art.

According to an embodiment of the invention, a switching device is provided with a first personal computer, having a first input device for the input of position and input information, such as in particular a cursor, and a first monitor with a first display area for displaying the position and input information, and a second personal computer, having a second monitor with a second display area for displaying position and input information, whereby the personal computers are connected by means of a first connection, and the personal computers have a first program, and the first program determines the relative position of the position information designated for display and assigns it to one of the display areas, and by means of a switching function the first program redirects the entered input information via the first connection to the personal computer connected to the assigned display area for display and/or processing. A switching is effected hereby according to the invention based on the relative position of the position information, so that the input information entered after the switching is redirected to the personal computer connected to the selected display area.

According to a further embodiment of the invention, a method is provided for switching from a first personal computer with a first input device for the input of position and input information and a first monitor with a first display area for displaying position and input information to a second personal computer with a second monitor with a second display area for displaying position and input information, whereby the personal computers are interconnected by means of a first connection, and a first program is installed in each case in the personal computers and the relative position of the position information designated for display is assigned by means of the first program to one of the display areas and the entered input information are redirected by means of a switching function of the first program via the first connection to the personal computer connected to the assigned display area for display and processing.

An advantage of the design of the invention is that the connected personal computers can be operated and controlled by means of a single input device in an especially simple and cost-effective manner without additional hardware or high data traffic between two connected personal computers by a program installed in the personal computers. Particularly in already existing personal computer systems, which are set up, for example, in especially hazardous environments preferably for process control, it is advantageous to control reliably and cost-effectively the other connected personal computers by means of a personal computer placed in a safe environment without subsequent changes to the hardware. Another advantage is that several personal computers, linked with one another, can be operated by means of a single input device such as, for example, a keyboard and/or a mouse and/or a touch-sensitive input field. It is conceivable in this case that both personal computers with their display areas are also located in a potentially explosive environment. In a refinement, the input device(s) can also be located in a safe environment. Further, costly releases are avoided which are unavoidable when changes are made to hardware in safety-relevant systems.

The first program set up to develop a solution of the invention determines the relative position of the position information to be shown on the particular display area. If the position information to be shown moves beyond the first display area, the input information is transferred to the second personal computer and vice versa. The transferred position and input information are processed in the second personal computer, usually by means of additional programs, and the part of the input information to be shown is displayed in the display area of the second personal computer. As soon as the position information is outside of the display area of the second personal computer, the entered position and input information is returned to the first personal computer by means of the first program and the input information is made available to the additional utility programs of the first personal computer. Tests by the applicant have shown that it is sufficient, for example, to check solely the data stream of the first input device by means of the first program and to assign it to one of the display areas. After the assignment has been made, which also causes switching to the personal computer selected in this way, the entered input information is provided to the assigned personal computer for processing. Accordingly, the data traffic between the connected personal computers is low, so that the exchange can be readily carried out also with data connections whose data rates are within the range of 50 kbit/s.

In an embodiment, the processing or further processing of entered input information can occur in the personal computer whose display area is selected for displaying by means of the position information. This is of advantage particularly in the case of inputs for process control, i.e., when each personal computer is connected to process machines. Preferred input devices comprise in particular a keyboard and/or a mouse and/or a trackball and/or video input devices and/or one or more touch screens and/or barcode readers and/or RFID reading devices and/or joysticks. The connection between the first input device and the first personal computer and/or the first connection between the personal computers can be made both wired and/or wirelessly.

According to an embodiment, the first connection can be formed via a LAN (Local Area Network) connection and comprises a distributor with at least one OSI layer. Such distributors are also called a “SWITCH” and are generally used for coupling a plurality of personal computers. In another refinement, a so-called HUB may also be used for creating a connection between the personal computers. Because of the type of design, an available network can be used for realizing the solution of the invention, without changes having to be made on the hardware side. Because the exchanged data rates are low, the solution of the invention represents only a minor load on the available network.

In another embodiment, the first connection is made as a serial connection, for example, by means of an RS232 or a USB connection. In this way, personal computers can be connected in an especially cost-effective manner. Further, the personal computers can also be connected by means of Bluetooth or IrDA or WLAN.

According to an embodiment, a plurality of personal computers, in which the first program is installed, can be controlled by the solution of the invention by means of a single input unit. It is advantageous in this regard that in the case of two or more input devices the first input device is preferred; i.e., a so-called master-slave arrangement is formed. In another refinement, a number of master and/or slave arrangements can be connected and preferably controlled overall or in part by means of a single input device. It is an advantage of the solution of the invention that maximum flexibility in the configuration of linked personal computers can be achieved.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a first embodiment with two personal computers; and

FIG. 2 shows a second embodiment with a plurality of personal computers, connected by means of a network.

### DETAILED DESCRIPTION

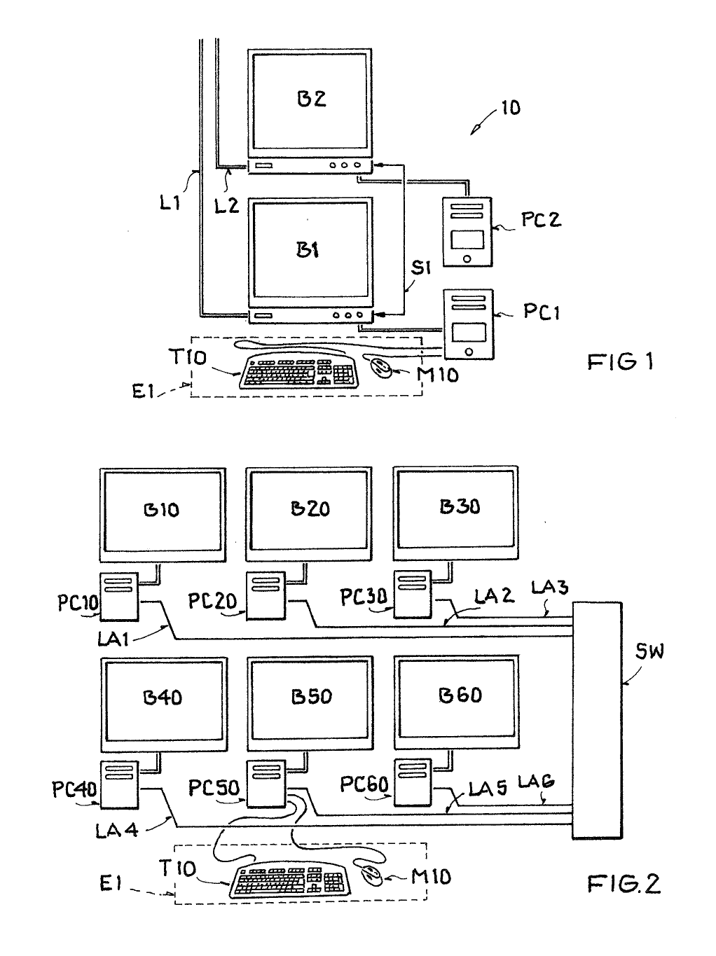

The illustration in FIG. 1 shows a first embodiment of a switching device 10, having a first personal computer PC1, with a first monitor with a first display area B1, a first network cable L1, and a first input device E1, formed as a keyboard T10 and a mouse M10, and a second personal computer PC2 with a second monitor with a second display area B2 and a second network cable L2. Both personal computers PC1 and PC2 are connected by means of a serial connection cable S1, which is formed preferably as a RS232 connection. A first program (not shown) is installed in both personal computers PC1 and PC2. Further, a plurality of other programs, such as, for example, operating system programs and programs for controlling automatic process machines, is installed in personal computers PC1 and PC2.

The principle of operation will be described below. The position information input by the first input device E1 or the relevant input data stream of keyboard T10 and/or mouse M10 are examined by means of the first program, installed in both personal computers PC1 and PC2, in regard to the extent to which the data for display on the selected monitor are available and their relative position with respect to the selected display area is determined. If the first program realizes that the position information designated for display is located outside the existing selected display area, it is redirected to the second personal computer PC2 with the second display area B2. The position and input information of keyboard T10 and/or mouse M10 is redirected by means of the first connection S1 from the first personal computer PC1 to the second personal computer PC2. In this way, the entered input information from the input devices, preferably keyboard T10 and/or mouse M10, is made available for processing to other utility programs installed in the respective personal computers. If a number of input devices are connected to different personal computers, in an embodiment in the case of a number of input devices, position and input information of all input devices that are not preferred can be effectively suppressed by means of the switching device of the invention or by means of the method of the invention.

In the illustration in FIG. 2, a personal computer PC10, in which the first program is installed and which has a monitor with a display area B10, is interconnected by means of a network cable LA1 with a switch SW. Switches of this type or hubs as well are necessary to connect a number of personal computers together into a network, for example, by means of an Ethernet connection. According to a refinement, a star-shaped connection of a master to the respective slave can also be made preferably by means of N−1 serial connections. It is sufficient in this case that the connection devices preferably have one OSI 2 layer, most preferably one OSI 1 layer. Further, a personal computer PC20, in which the first program is installed and which has a monitor with a display area B20, is interconnected by means of a network cable LA2 with the switch SW. Further, a personal computer PC30, in which the first program is installed and which has a monitor with a display area B30, is interconnected by means of a network cable LA3 with the switch SW. In addition, a personal computer PC40, in which the first program is installed and which has a monitor with a display area B40, is interconnected by means of a network cable LA4 with the switch SW. Moreover, a personal computer PC50, in which the first program is installed and which has a monitor with a display area B50, a keyboard T10, and a mouse M10, is interconnected by means of a network cable LA5 with the switch SW. Further, a personal computer PC60, in which the first program is installed and which has a monitor with a display area B60, is interconnected by means of a network cable LA6 with the switch SW.

If the pointer is now moved beyond display area B50 of personal computer PC50, which is preferable formed as a master, preferably by means of mouse M10, the input position information and then in succession also the entered input information are redirected to a neighboring display area of a personal computer. In this way, the assigned personal computer receives the input focus, and is therefore selected and active. It is advantageous that all other personal computers are inactive.

In the present embodiment, for this purpose, the number of the personal computers or their network names, preferably the IP address, is communicated to the first program. Further, the arrangement of the monitor assigned to the particular personal computer is communicated to the first program. If in the present case, for example, the pointer is now moved to the right out of display area B50, the input data stream is redirected to PC60 with display area B60 by means of the first program and the pointer is shown solely on display area B60. If the pointer in display area B60 is moved toward the right out of the display area, the pointer is shown on display area B40 and vice versa. If the pointer is moved upward or downward from display area B40 beyond the display area, the pointer is shown on screen B10. Accordingly, the pointer is shown on display areas B20 or B30, when, for example, the pointer starting with a pointer in display area B10 is moved further and further to the right, to be shown finally again on the left side of display area B10.

As a result of the switching, the input information of keyboard T10 and mouse M10 is redirected to the personal computers PC10 to PC60 connected to the monitors, so that the connected personal computers PC10 to PC60 are controlled with a single mouse and/or keyboard. If the pointer is, for example, in display area B50, the utility programs of PC50 can be influenced by means of the entered input information. The neighboring personal computers simultaneously execute the programmed monitoring tasks and/or control tasks.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A switching device comprising:
a first personal computer having a first input device for an input of position information and a first monitor with a first display area for displaying information; and
a second personal computer having a second monitor with a second display area for displaying position information, the first and second personal computers being connectable to one another via a first connection,
wherein the first and second personal computers each have a first program and the first program determines a relative position of position information designated for the display and assigns it to a display area and redirects entered position information by a switching function via the first connection to the personal computer connected to the assigned display area for display.

2. The switching device according to claim 1, wherein processing of the input position information occurs in the personal computer whose display area is selected for displaying the position information.

3. The switching device according to claim 1, wherein the first input device comprises a keyboard and/or a mouse.

4. The switching device according to claim 1, wherein the first connection is made as a wired or wireless connection.

5. The switching device according to claim 1, wherein the first connection comprises a distributor with at least one OSI layer.

6. The switching device according to claim 1, wherein the first connection is made as a serial connection.

7. The switching device according to claim 1, wherein a plurality of personal computers have a first program.

8. The switching device according to claim 1, wherein, in the case of a number of input devices, the first input device is preferred.

9. A method for switching from a first personal computer with a first input device for the input of position information and a first monitor with a first display area for displaying position information to a second personal computer with a second monitor with a second display area for displaying position information, the method comprising:
interconnecting the first and second personal computers via a first connection;
installing a first program to each of the personal computers;
determining a relative position of position information designated for display via the first program and assigned to a display area; and
wherein, via a switching function of the first program, the display is redirected via the first connection to the personal computer connected to an assigned display area.

10. The method for switching according to claim 9, wherein processing of the entered position information is carried out by the personal computer whose display area is selected for displaying the position information.

11. The method for switching according to claim 9, wherein the input of position information is carried out by a keyboard and/or a mouse.

12. The method for switching according to claim 9, wherein the first connection is made as a wired or wireless connection.

13. The method for switching according to claim 9, wherein the redirection of position information is carried out by a first distributor with at least one OSI layer connection.

14. The method for switching according to claim 9, wherein a plurality of personal computers are connected.

15. The method for switching according to claim 9, wherein in the case of a connection of a number of input devices to a number of personal computers the input of the first input device is processed and displayed preferentially.
